(19) United States
(12) Patent Application Publication
(10) Pub. No.: US 2002/0186033 A1
(43) Pub. Date: Dec. 12, 2002

(54) Sensing apparatus having a cut-plane sensor and signal conditioner formed in a seamless monolithic substrate

(76) Inventors: Marshall E. Smith JR., Eaton, FL (US); Richard W. Stettler, Winter Haven, FL (US); Peter U. Wolff, Winter Haven, FL (US)

Correspondence Address: Allen, Dyer, Doppelt, Milbrath & Gilchrist, P.A., Suite 1401, 255 South Orange Avenue, P.O. Box 3791, Orlando, FL, 32802-3791, US

(21) Appl. No.: 10/136,180

(22) Filed: May 1, 2002

Related U.S. Application Data
(60) Provisional application No. 60/287,856, filed on May 1, 2001.
(60) Provisional application No. 60/288,312, filed on May 2, 2001.
(60) Provisional application No. 60/288,313, filed on May 2, 2001.
(60) Provisional application No. 60/288,282, filed on May 2, 2001.
(60) Provisional application No. 60/288,281, filed on May 2, 2001.
(60) Provisional application No. 60/288,279, filed on May 2, 2001.

(51) Int. Cl. G01R 31/02

(52) U.S. Cl. 324/763

(57) ABSTRACT

A sensing apparatus having a sensor and signal conditioner angled relative to each other at a predetermined angle and formed in a seamless monolithic semiconductor substrate is provided. The sensor is formed in the cut plane of the seamless monolithic semiconductor substrate. The signal conditioner is formed in a wafer surface of the same seamless monolithic semiconductor substrate. The sensor generates a sensing signal in response to a preselected physical stimulus. The signal conditioner is electrically connected to the sensor to condition the signal generated. The seamless monolithic semiconductor substrate can be mounted on a mounting base and encapsulated in an encapsulation to provide a protective cover. An additional conductor connected to the signal conditioner and extending outwardly from the encapsulation connects the sensing apparatus to a remote electrical device such as a sensing monitor.

### RELATED APPLICATIONS

This application claims priority to Provisional Application Serial No. 60/287,856, filed May 1, 2001, and incorporates by reference the disclosures of Provisional Application No. 60/288,312 filed May 2, 2001, Provisional Application Serial No. 60/288,313 filed May 2, 2001, Provisional Application Serial No. 60/288,282 filed May 2, 2001, Provisional Application Serial No. 60/288,281 filed May 2, 2001, and Provisional Application Serial No. 60/288,279 filed May 2, 2001.

### FIELD OF THE INVENTION

The present invention relates to the field of sensing apparatuses and, more particularly, to the field of sensing apparatuses and methods for forming sensing apparatuses.

### BACKGROUND OF THE INVENTION

Sensing apparatuses are widely used in mechanical and electrical systems for detecting and measuring a myriad of physical or chemical phenomena. Among the various uses for such devices, for example, are sensing the presence and intensity of electrical and magnetic fields. Sensing devices are also commonly used, for example, to detect mechanical forces, measure the temperature or flow of a liquid or gas, or register the acceleration of a solid body. Designers of sensing devices confront conflicting requirements in the quest for an efficient and effective sensing apparatus. Typically, the mechanical and electrical systems in which such sensing devices are utilized are subject to various conditions that can adversely affect the operating performance of the apparatus. These adverse conditions include, for example, extreme accelerations and vibrations, intense temperature variations, corrosive chemicals, and electrostatic discharges.

Thus, the sensing apparatus must have a sufficiently robust structural integrity if it is to perform optimally in such harsh environments and under such extreme conditions. Secondly, because the mechanical and electrical systems in which sensing devices are commonly used are themselves becoming ever more compact, the allocation of space for the included sensing apparatus must be optimized. Therefore, in addition to being structurally robust, an optimally designed sensing apparatus must also be as small as possible. This latter requirement is an especially challenging design consideration given that the number of components needed for such mechanical and electrical systems can increase as the systems become increasingly complex and are employed for an ever greater number of signaling tasks. Thirdly, as sensing apparatuses are tasked to provide an ever greater number of signaling functions in increasingly varied settings, there is a greater challenge to keep signal conditioning circuitry from becoming overly cumbersome and complex as it powers the sensing component, conditions the sensing signal, and provides signal amplification to overcome electromagnetic fields or extraneous noise factors. And finally, the sensing apparatus should be efficient in terms of being capable of cost-efficient installation as well as being simple to service.

Thus, an optimally designed field sensing apparatus is one that is rugged in terms of structure, small in size, capable of providing accurate signal responses to complex physical phenomena, and yet designed with sufficient simplicity to be easily installed and maintained in a mechanical or electrical system. The challenge posed for designers lies in the fact that these requirements frequently conflict. A small, rugged sensing apparatus would contain a minimum number of electronic devices so as to reduce the probability that a connection will fail due to vibration, shock, or temperature-induced expansions or contractions. Weighing against this objective, however, is the requirement that the sensing apparatus be sophisticated enough to detect and process sensed signals that are discernable despite external noise. This latter requirement, however, ordinarily necessitates complex and sometimes cumbersome signal conditioning circuitry that accordingly increases the complexity and size of the sensing apparatus. A major design goal, therefore, is to provide a sufficiently sophisticated set of circuitry that is complex enough to discern and respond to physical phenomena without adversely affecting its structural integrity by unduly increasing the number and complexity of electrical connections, all while simultaneously making the sensing apparatus as small as possible.

The typical sensing device is a set of electrical components manufactured on a semiconductor substrate or “chip” cut from a semiconductor wafer. Temperature changes exert a strong influence on the electrical conductivity and other properties affecting the devices' operating characteristics. Because most of the mechanical and electrical systems in which a sensing apparatus is utilized are exposed to extreme temperature variations, the effects of temperature must be controlled in the sensing apparatus. This ordinarily is the function of the signal conditioning circuitry which amplifies or otherwise conditions the signal generated by the sensing component. The signal conditioner is also needed for other functions such as compensating for a signal that is too low to overcome noise effects and to increase the signal for relay to a remotely located monitor. As the number and complexity of signal conditioning functions increase, so, too, does the size of the signal conditioning circuitry. Accordingly, the overall size of the sensing apparatus increases as well. Therefore, the signal conditioning circuitry can be a limitation on the design of a reduced-size apparatus.

A further limiting condition arises because the sensitivity of the sensing apparatus is affected by the orientation of the sensing component relative to the force or field to be sensed. Maximum sensing sensitivity requires a precise orientation of the sensing component. If the sensing component and the signal conditioning circuitry are formed on the same surface plane of a semiconductor, the signal conditioning circuitry, of necessity, will have the same orientation as the sensing component. Orientation of both the sensing component and the signal conditioning circuitry in the identical plane produces a larger cross section for the sensing apparatus than could otherwise be achieved by orienting the sensing component to the field and separately orienting the signal conditioning circuitry so as to reduce the overall dimension of the sensing apparatus cross section.

Various devices have attempted to deal with some of the multiple, competing objectives of an efficient, compact sensing apparatus. Applicants' own U.S. Pat. No. 6,002,252 titled Compact Sensing Apparatus Having Transducer and Signal Conditioner with a Plurality of Mounting Pins and U.S. Pat. No. 6,187,609 titled Compact Sensing Apparatus Having Reduced cross Section and Methods of Mounting, for example, teach the advantages of methods for forming a sensing apparatus having a transducer and signal conditioning circuitry connected via wire pins and mounted on distinct surfaces at a predetermined angle so as to reduce the overall the lengthwise extent of the sensing apparatus. Applicants' U.S. Pat. No. 5,670,886, moreover, discloses an apparatus having signal conditioning circuitry formed in a surface portion of single semiconductor substrate and a magnetic sensing element formed in an orthogonal edge of the same substrate and connected via metal conductors to the signal conditioning circuitry.

Devices employed in the fields of digital imaging and optical detecting also have attempted, with varying degrees of success, to deal with many of the same problems confronting designers of compact sensing apparatuses and facing conflicting efficiency objectives in terms of apparatus size, sensing element orientation, and structural integrity of the device. U.S. Pat. No. 5,869,896 issued to Baker et al. and titled Packaged Electronic Module and Integral Sensor Array, for example, describes attempts to make a small, lightweight, real-time, wide-field view imager by constructing a “monolithic electronic module” formed from “multiple bare semiconductor chips (i.e., semiconductor dies), laminated together into a unified stack.” A sensor is then “coupled” to the stack and connected to other circuitry contained thereon through a thin-film metallization layer along an edge. U.S. Pat. No. 4,403,238 issued to Clark and titled Detector Array Focal Plane Configuration describes similarly describes “a stack, or sandwich, comprising numerous silicon chips, or substratess, escured together by suitable adhesive material.” More specifically, Clark describes an electro-optical detector formed from “a multiplicity of layers” of a semiconductor and mounted on a supporting block. A detector “mosaic” is then coupled to the stack similar to the device in Baker et al.

Notwithstanding these attempts to deal with the competing constraints and objectives of an efficient compact sensing apparatus, there remains a need for a device not requiring the stacking or sandwiching of multiple semiconductor layers to which a sensor must be coupled. Stacked layers pose problems in terms of both the effectiveness and reliability of the device as well as the efficiency in forming such devices. More specifically, increasing the number of layers to accommodate the device's required circuitry increases the discrete electrical connections that must be formed and the number of physical couplings of semiconductor layers that must be made. There is, accordingly, increased risk that the connections can be undone or the layers uncoupled whenever the device is subjected to even the ordinary stresses encountered in most standard operating modes. This risk increases virtually in direct correlation to the number of layers and connections required to a multi-layered device. In addition, the separate forming steps rises in virtual lock-step as each new layer must be formed and then electrically coupled in building the stack. These additional steps are especially burdensome if one is attempting to form an integral substrate having a multi-layered surface formed into a single edge having a precise angle as would be necessary if one were attempting to position the sensor and related conditioning circuitry on two distinct surfaces at a predetermined angle.

### SUMMARY OF THE INVENTION

With the foregoing in mind, the present invention advantageously provides a sensing apparatus comprising sensing component circuitry (“sensor”) and signal conditioning circuitry (“signal conditioner”) whereby the sensor and signal conditioner are angled optimally relative to each other so as to simultaneously orient the sensor for maximum sensing sensitivity while minimizing the overall size of the sensing apparatus. Thus, the present invention provides for optimal orientation of a sensor and corresponding signal conditioner on a reduced-sized sensing apparatus. Moreover, the sensing apparatus is formed from a single monolithic substrate. The present invention further provides for efficiently and effectively connecting the sensor and signal conditioner on the monolithic substrate. Moreover, the present invention provides a method for forming such an optimally designed sensing apparatus. In addition, the present invention further provides a method for efficiently forming a plurality of such optimally designed sensing devices.

According to the present invention, the sensor and signal conditioner are formed on and, preferably, from a single monolithic substrate composed of a preselected semiconductor material. The sensor is formed on a first surface portion of the single monolithic semiconductor substrate, and the signal conditioner is formed on a second surface portion of the same monolithic substrate, each being electrically connected to the other. Preferably, the first and second surface portions are oriented with respect to each other at a predetermined angle that is greater than one hundred eighty (180) degrees, the predetermined angle being defined as the angle of rotation between an imaginary initial plane extending parallel to the second surface portion and an imaginary terminal plane extending parallel to the first surface portion.

Thus, because the sensor ordinarily extends substantially parallel with the surface portion on which it is formed, and the signal conditioner, likewise, extends substantially parallel with the surface portion on which it is formed, the sensor and the signal conditioner are also oriented with respect each other at the same predetermined angle. Preferably the predetermined angle is at least about two hundred fifty (250) degrees but no more than about two hundred ninety (290) degrees so that the sensor and signal condition are positioned substantially orthogonally relative to each other on the same monolithic substrate. The ability to angle the sensor relative to the signal conditioner provides distinct advantages. As detailed below, among the benefits provided by the present invention are enhanced sensitivity of the sensor and reduced size of the sensing apparatus on which the sensor and signal conditioner are positioned.

The sensor provides an electrical signal in response to a predetermined stimulus. The stimulus can be an electric field, a magnetic field, pressure, heat, or any other of a host of physical and chemical phenomena. Specifically, electrical or magnetic field sensors include position-and-proximity sensors such as Hall effect, magneto-resistor, capacitive, and inductive sensors, as well as electric current sensors. Mechanical force sensors include sensors that respond to the pressure or flow of a fluid, to stress forces, to the weight of an object, or to the acceleration of a body. Generally, there is a preferred orientation for such sensors that maximizes the sensitivity of the sensor to the particular physical stimulus that elicits a signal response from the sensor.

In many practical contexts, the sensor will unavoidably be exposed to extraneous electrical or magnetic fields or mechanical forces. Orienting the sensor relative to such extraneous fields or forces can reduce the sensitivity of the sensor to these extraneous effects. Preferably, the sensing apparatus includes a signal conditioner electrically connected to the sensor to amplify or otherwise condition the signal generated by the sensor in response to the predetermined stimulus. For example, the signal generated by the sensor can be too low in magnitude to overcome noise caused by extraneous effects. The signal conditioner amplifies the signal generated by the sensor to overcome the noise. Similarly, the signal generated by the sensor may need to be transmitted a considerable distance to a remotely located monitoring circuit. Here, again, the signal conditioner can amplify the signal generated by the sensor so as to efficiently and effectively convey the signal the necessary distance.

As alluded to above, there are multifold advantages associated with the angling of the sensor relative to the signal conditioner on a single monolithic substrate as provided by the present invention. Among these are the reduced dimensions of the sensing apparatus as compared with devices having a sensor and signal conditioning circuitry positioned on a common planar surface. Generally, signal conditioning circuitry has a greater lengthwise extent by a factor of at least five (e.g., 100 mils for the signal conditioner versus 20 mils for the sensor). To the degree that the sensor is angled relative to the signal conditioner, the dimensions of the sensing apparatus accordingly are reduced. Optimally, the sensor is oriented orthogonally to the signal conditioner.

Moreover, as already noted, the sensitivity of the sensor is enhanced by specifically orienting the sensor relative to the fields and forces to which the sensor is responsive and the extraneous effects to which the sensor is subject. The ability to angle the sensor on the sensing apparatus provides the maximum degrees of freedom in orienting the sensor for enhancing the sensitivity and effectiveness of the sensor. Flexibility in orientation of the sensor thus is another salient advantage of the present invention. Perhaps most importantly, these distinct advantages are achieved without any reduction in reliability of the sensing apparatus. The present invention does not rely on forming the sensor and signal conditioner on separate substrates that subsequently conjoined. Even more significantly, the present invention does not from the sensor by forming the sensor and signal conditioner on the same surface of a common substrate and then cutting the substrate into two pieces—one on which the sensor is formed, the other on which signal conditioning circuitry is formed—before joining the pieces at an angle so as to reorient the sensor and signal conditioner.

Definite advantages are derived from forming the sensor and signal conditioner both on and preferably from the same monolithic substrate that need not be cut in order to optimally angle the sensor and the signal conditioner relative to each other. While joining separate substrates or pre-cut pieces allows for angling the sensor in relation to the signal conditioning circuitry, there are distinct advantages the joining of separate substrates posses disadvantage. Among these advantages are a reduction in the electrical connections otherwise needed to connect components on separate substrates or pieces and the enhanced structural integrity provided by an uncut monolithic substrate that has not been formed from separate, cut pieces. Under extreme operating conditions electrical and structural connections may come undone. Thus, the reliability of a sensing apparatus formed from an uncut monolithic substrate having minimal circuitry connections and no structural connections separately joined is accordingly enhanced by comparison to one formed by joining separate substrates or substrate pieces substrates. Thus, a salient advantage of the present invention is that it provides the maximum degrees of freedom in orienting the sensor on the substrate to thereby enhance sensitivity of the sensor and reduce the size of the sensing apparatus, while simultaneously forming the sensor and signal conditioner on a single monolithic semiconductor substrate to thereby avoid imperfections associated with conjoining separate substrates.

Further advantages are provided by compactly mounting the sensing apparatus. The mounted sensing apparatus preferably includes a mounting base, semiconductor substrate, sensor formed on a first surface portion of the substrate, and a signal conditioner formed on a second surface portion of the substrate. The mounting base can be any support frame, such as a lead frame having metal pins and electrical connectors extending from the signal conditioner to connect the sensor to a separate device such as a remote monitor. Preferably, however, the mounting base comprises a flexible ribbon cable comprising at least one electrical conductor encased within the flexible ribbon cable for conducting electrical signals.

The sensing apparatus, moreover, preferably includes connecting means positioned on the mounting base and electrically connected to at the signal conditioner to provide a juncture at which an electrical connection can be made between the sensing apparatus and any preselected electrical device such as a remotely located monitor. The connecting means includes, for example, wire bonding via wire bond pads positioned between the signal conditioner and the at least one electrical conductors encased by the flexible ribbon cable. The electrical connection can alternatively be effected by means of conductive epoxy bonds to establish the electrical connection between the signal conditioner and at least one electrical conductor enclosed in the flexible ribbon cable.

Further advantages are achieved if the compactly mounted sensing apparatus also includes a protective, insulating encapsulation housing to encase at least a portion of the mounting base and at least a portion of the signal conditioner mounted thereto. The encapsulation housing can be for example, a molded plastic or other material formed to fit over preselected portions of the mounting base and signal conditioning circuitry, and possibly the sensor. Preferably, then, the flexible ribbon cable and corresponding at least one electrical conductor extend through the housing in order to provide an electrical connection to a separate device such as a remotely located monitor.

The compactly mounted sensing apparatus preferably further includes at least one recess being formed in a surface portion of the semiconductor substrate thereby defining an encapsulation well within which a portion of the encapsulation housing extends. The encapsulation well thereby increases the contact between the mounting base and the encapsulation housing, which accordingly reduces the probability that the mounting base will be pulled away from the encapsulation housing. The device can be made even more secure by including at least a portion of a surface of the mounting base that is roughened to thereby increase friction at a point of contact between the mounting base and the encapsulation housing. Alternatively, the edge of the substrate can be serrated or grooved to connect more securely with the encapsulation housing.

For magnetically actuated sensors such as a Hall cell sensor, the sensing apparatus can further include a magnet positioned beneath the single monolithic substrate. For example, the magnet can be positioned adjacent a surface portion of the mounting base on a side of the mounting base opposite to the side on which the single monolithic substrate is positioned.

Further benefits are provided by various method aspects of the present invention, including a method for forming a compact sensing apparatus on a single monolithic substrate. The single semiconductor substrate can be cut from a wafer by conventional means such as with a diamond saw cutter, but preferably, is formed by cutting the semiconductor wafer by delivering high concentrations of energy along dimensions of the wafer corresponding to dimensions of the substrate to be cut from the wafer. Such cutting at least partially alleviate cracks in the substrate and at least partially smooths the top and end surfaces of the substrate while also at least partially straightening the angled edges of the substrate. Preferably, the energy delivered is in the form of coherent electromagnetic radiation generated by a laser and thus conveyed for cutting the wafer as a narrow beam of light energy. The single semiconductor substrate also can be annealed following cutting from the semiconductor wafer to further alleviate cracks in the substrate and the surfaces of the substrate.

The method includes forming an insulation layer on a semiconductor substrate having a top substrate surface and an end substrate surface oriented with respect to each other at a predetermined angle greater than one hundred eighty (180) degrees, the predetermined angle being defined as previously to be the angle of rotation between an initial plane extending substantially parallel to the top substrate surface and an imaginary terminal plane extending substantially parallel to the end substrate surface. The insulation layer is formed in a position adjacent the end substrate surface and preferably has a thickness sufficient to ensure that the apparatus retains an insulation layer despite any diffusion of the semiconductor material of the substrate into the insulation layer that may occur during formation of the compact sensing apparatus.

The method further includes the step of forming a sensor on the end surface of the single monolithic semiconductor substrate. The method preferably also includes applying a temporary protective passivation layer over the monolithic substrate over at least the sensor to protect the sensor during subsequent formation of the signal conditioner. The method further comprises forming a signal conditioner electrically connected to the sensor on the same semiconductor substrate and formed on the top substrate surface of the same monolithic semiconductor substrate.

The method for forming a compact sensing apparatus, moreover, can include forming a conductive passivation region positioned between the sensing component and the signal conditioner. The conductive passivation region preferably is formed by a metal layer that can be etched to form at least one trace connection between the sensing component and the signal conditioner. Alternatively, the conductive region can be formed by creating a layer of conductive epoxy that can be etched to form at least one electrical connection between the sensing component and the signal conditioner.

A further method aspect of the present invention is provided for efficiently and economically forming a plurality of compact sensors. The method includes forming a plurality of sensors on a single strip of semiconductor material, the strip having a top surface and an end surface oriented with respect to each other at a predetermined angle greater than one hundred eighty (180) degrees. Again, the predetermined angle is defined as the angle of rotation between an imaginary initial plane extending substantially parallel to the top surface and an imaginary terminal plane extending substantially parallel to the end surface. Preferably, the plurality of sensors are formed on the end surface or the strip of semiconductor material. The method further includes forming a plurality of signal conditioners on the same semiconductor strip. Each of the plurality of signal conditioners is preferably formed on the top surface of the same strip and electrically connected to a corresponding sensor formed on the same strip. The plurality of sensors and corresponding signal conditioners having been formed on the single strip of semiconductor material, the strip is cut at predetermined intervals to form a plurality of compact sensing apparatuses, each sensing apparatus comprising a sensor and a corresponding signal conditioner electrically connected to the corresponding sensor positioned on a single monolithic substrate.

Preferably, the semiconductor strip is cut from a semiconductor wafer that itself has been sliced from a silicon crystal ingot. Moreover, the lateral extent of the strip is preferably equal to the lengthwise extent of each of the sensing apparatuses that ultimately is formed by the method.

Once each of the plurality of compact sensing apparatuses has been formed and cut from the single semiconductor strip, each such apparatus can be mounted on a base. Moreover, each mounted sensing apparatus can be positioned within a housing that encases at least a portion of the mounted sensing apparatus.

### BRIEF DESCRIPTION OF THE DRAWINGS

Some of the features, advantages, and benefits of the present invention having been stated, others will become apparent as the description proceeds when taken in conjunction with the accompanying drawings in which:

FIG. 1A is a perspective view of a semiconductor wafer being sliced from a semiconductor ingot for forming a sensing apparatus according to the present invention;

FIG. 1B is a perspective view of a semiconductor wafer from which a plurality of seamless semiconductor substrates is cut for forming a plurality of sensing apparatuses according to the present invention;

FIG. 1C is perspective view of a plurality of seamless semiconductor substrates from which a plurality of sensing apparatuses is formed according to the present invention;

FIG. 1D is a perspective view of a plurality of seamless semiconductor substrates on which are formed a plurality of sensors is formed for forming a plurality of sensing apparatuses according to the present invention;

FIG. 1E is a perspective view of a plurality of semiconductor substrates on which a plurality of sensors and corresponding signal conditioners is formed according to the present invention;

FIG. 1F is a perspective view of a plurality of sensing apparatuses each having a sensor and signal conditioner formed in a seamless semiconductor substrate according to the present invention;

FIG. 2A is a perspective view of a semiconductor wafer being sliced from a semiconductor ingot for forming a sensing apparatus according to the present invention;

FIG. 2B is a perspective view of a semiconductor wafer from which a plurality of seamless semiconductor substrates is cut for forming a plurality of sensing apparatuses according to the present invention;

FIG. 2C is perspective view of a plurality of seamless semiconductor substrates from which a plurality of sensing apparatuses is formed according to the present invention;

FIG. 2D is a perspective view of a plurality of seamless semiconductor substrates on which are formed a plurality of sensors is formed for forming a plurality of sensing apparatuses according to the present invention;

FIG. 2E is a perspective view of a plurality of sensing apparatuses each having a sensor and signal conditioner formed in a seamless semiconductor substrate according to the present invention;

FIG. 3 is a perspective view of a sensing apparatus according to the present invention;

FIG. 4 is a side elevational view of a sensing apparatus according to the present invention;

FIG. 5 is perspective view a sensing apparatus according to the present invention;

FIG. 6 is a top plane cross sectional view taken along line 6-6 in FIG. 5 of a sensing apparatus according to the present invention;

FIG. 7 is perspective view of a sensing apparatus according to the present invention;

FIG. 8 is a side cross sectional view taken along line 8-8 in FIG. 7 of a sensing apparatus according to the present invention;

FIG. 9 is a side elevational view of a sensing apparatus according to the present invention;

FIG. 10 is schematic flow of a method for forming a sensing apparatus having a sensor and signal conditioner angled relative to each other and formed in a seamless monolithic semiconductor substrate according to the present invention;

FIG. 11 is schematic flow of a method for forming a plurality of sensing apparatuses each having a sensor and signal conditioner angled relative to each other and formed in a seamless monolithic semiconductor substrate according to the present invention; and

FIG. 12 is a perspective view of a sensing apparatus according to the present invention illustrating a predetermined angle for a cut plane.

### DETAILED DESCRIPTION OF PREFERRED EMBODIMENTS

The present invention will now be described more fully hereinafter with reference to the accompanying drawings which illustrate preferred embodiments of the invention. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, the prime notation, if used, indicates similar elements in alternative embodiments.

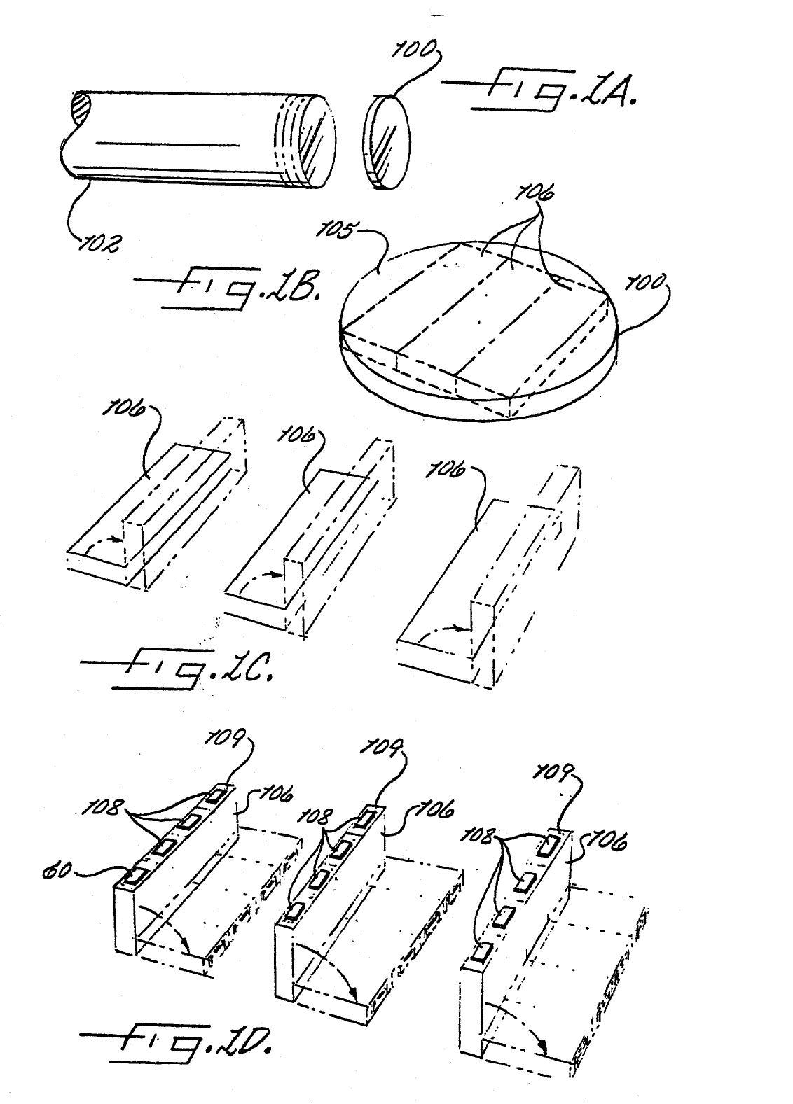

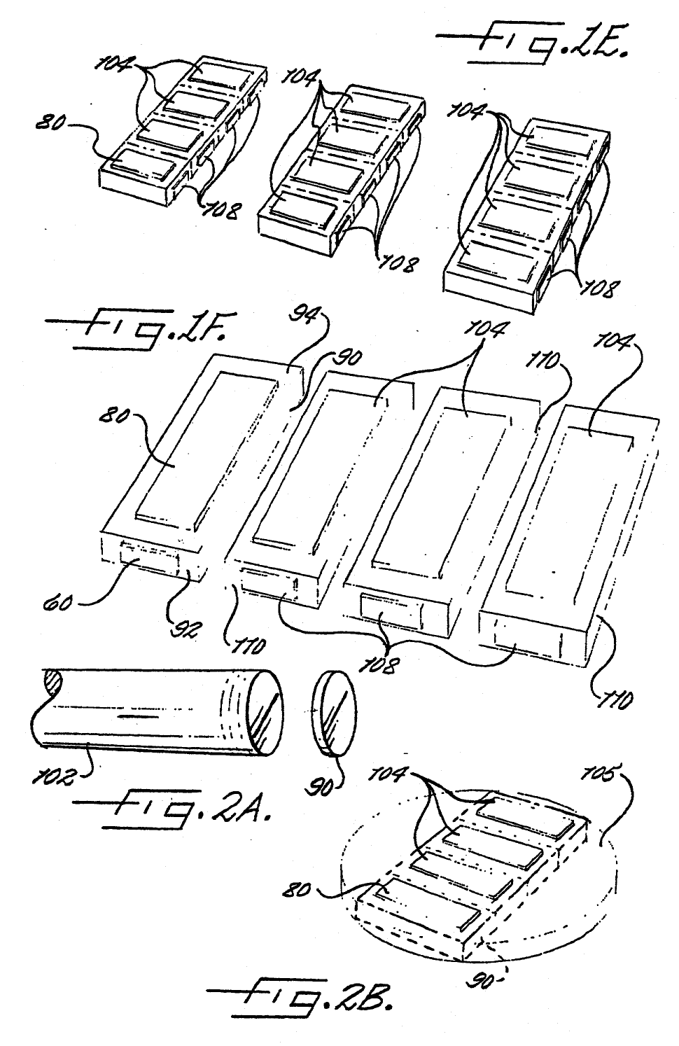

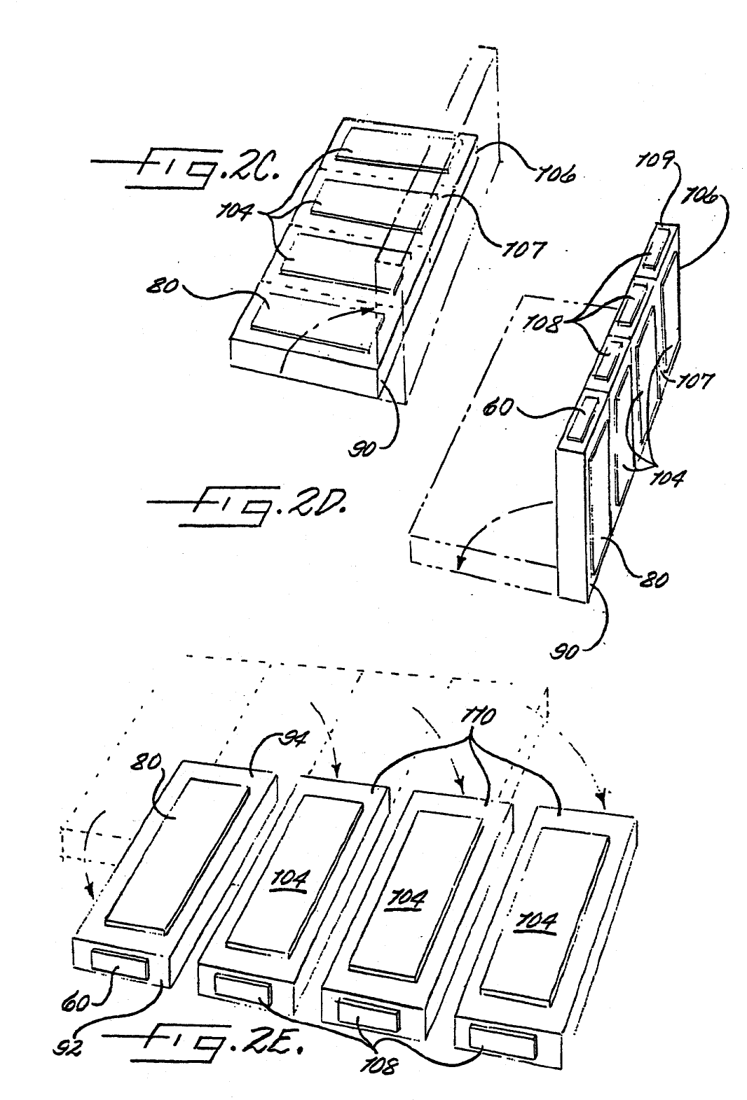

FIGS. 1-3. illustrates a compact sensing apparatus 40 comprising a sensor 60 and, electrically connected to the sensor, signal conditioning circuitry defining a signal conditioner 80. Both the sensor 60 and the signal conditioner 80 are formed in a single, seamless monolithic substrate 90. The sensor 60, more specifically, is formed on a cut plane 92 (defined explicitly below) of the seamless monolithic substrate 90, and the signal conditioner 80 is formed on a wafer surface 94 of the same seamless monolithic substrate 90. The seamless monolithic substrate 90 is formed from a semiconductor wafer 100, which itself typically will have been sliced from an ingot of semiconductor material 102 as will be readily understood by those familiar with the art of manufacturing semiconductor devices.

As further illustrated in FIGS. 1-3, the sensing apparatus 40 comprising a sensor 60 formed on a cut plane 92 of a seamless monolithic substrate 90 and a corresponding signal conditioner 80 formed on the wafer surface 94 of the same seamless monolithic substrate 90 is but one of several such sensing apparatuses 40, 110 that can be formed from the same semiconductor wafer 100 sliced from a semiconductor ingot 102. Specifically, a plurality of primary substrates 106 is “cut” from a single semiconductor wafer 100 by slicing through opposing wafer surfaces of the semiconductor wafer 100. The cutting of the wafer 100 and subsequent separation of the portions so cut from the wafer 100 yield the plurality of primary substrates 106, each of which has at least one cut plane 92, 109 corresponding to internal portions of the wafer exposed by the cutting through of the wafer 100 to form each of the primary substrates 106. Each of the primary substrates 106 also has opposing wafer surfaces that correspond to portions of the wafer from which each substrate was cut.

A plurality of sensors 60, 108 is then formed on a cut plane 109 of each of the plurality of primary substrates 106. Subsequently, signal conditioning circuitry defining a plurality of signal conditioners 80, 104 is formed on wafer surfaces 107 of each of the plurality of primary substrates 106. The primary substrates 106 are then cut along dimensions between each of the sensors 60, 108 and corresponding signal conditioners 80, 104 to form a plurality of seamless monolithic semiconductor substrates 90, 110, each having a sensor 60, 108 and corresponding signal conditioner 80, 104 angled relative to each other and formed therein.

So formed, then, the seamless monolithic substrate 90 has two surfaces (portions of the opposing surfaces of the wafer 100 from which the substrate 90 has been cut), one defining the wafer surface 94 in which the signal conditioner 80 is formed, and at least one angled-edge portion forming a cut plane 92 in which the sensor 60 is formed. The cut plane 92, specifically, is parallel to a plane through which the wafer has been cut. The sensor 60 and the signal conditioner 80 are, therefore, angled relative to each other at a predetermined angle corresponding to the angle between the cut plane 92 and the wafer surface 94 in which the sensor 60 and signal conditioner 80, respectively, are formed.

A significant advantage of the present invention, accordingly, is the ability to angle the sensor 60 and the signal conditioner 80 relative to each other while forming both in the same uncut, seamless monolithic substrate 90. The function of the sensing apparatus 40 is to sense a particular physical stimulus. It will have greatest sensing sensitivity is oriented properly relative to the physical stimulus it is to sense. The sensing apparatus ordinarily does not operate in isolation, however, but as part of a system and hence should be as small as possible. An efficient sensing apparatus 40, therefore, is one which optimizes the trade-off between orientation of the sensor 60 relative to sensing stimuli so as to enhance sensing sensitivity, on one hand, while on the other hand simultaneously orienting the sensor 60 and the signal conditioner 80 relative to each other so as to reduce the overall dimensions of the sensing apparatus 40.

Moreover, operative efficiency is enhanced if the sensor 60 and signal conditioner 80 are formed in a single, seamless semiconductor substrate 90. For example, there is much less chance that when that mechanical stress will separate the sensor 60 from the signal conditioner 80 or break the necessary electrical connections between the sensor 60 and the signal conditioner 80 when the sensing apparatus 40 is employed in a harsh environment. Moreover, the conductive properties of the substrate are accordingly more reliable when the sensor 60 and the signal conditioner 80 are both formed in the single, seamless monolithic semiconductor substrate 90. Therefore, the present invention is uniquely advantageous in terms of permitting the sensor 60 and the signal conditioner 80 to be angled relative to each other on and formed in the same uncut, seamless monolithic substrate 90.

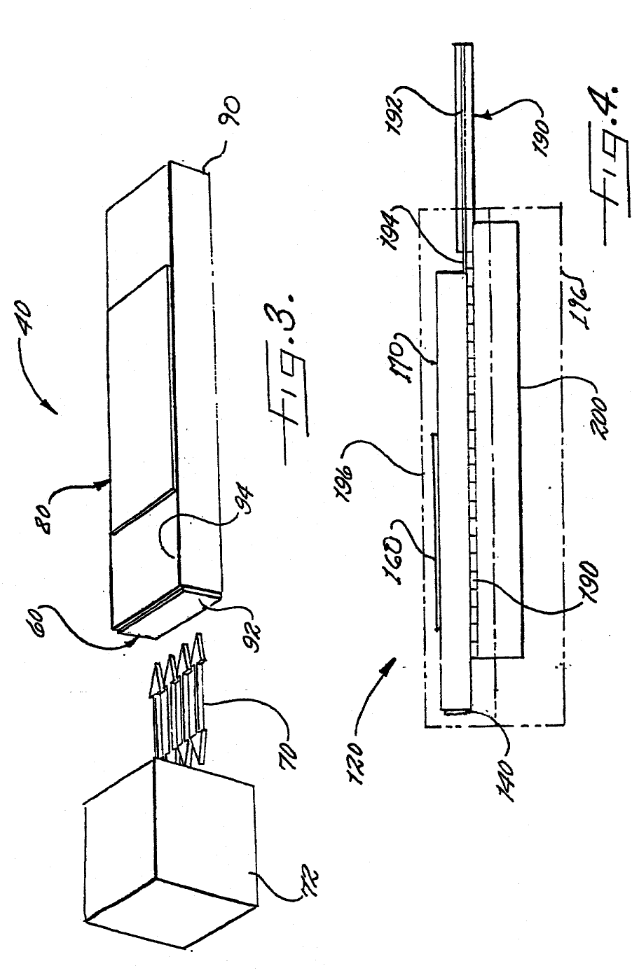

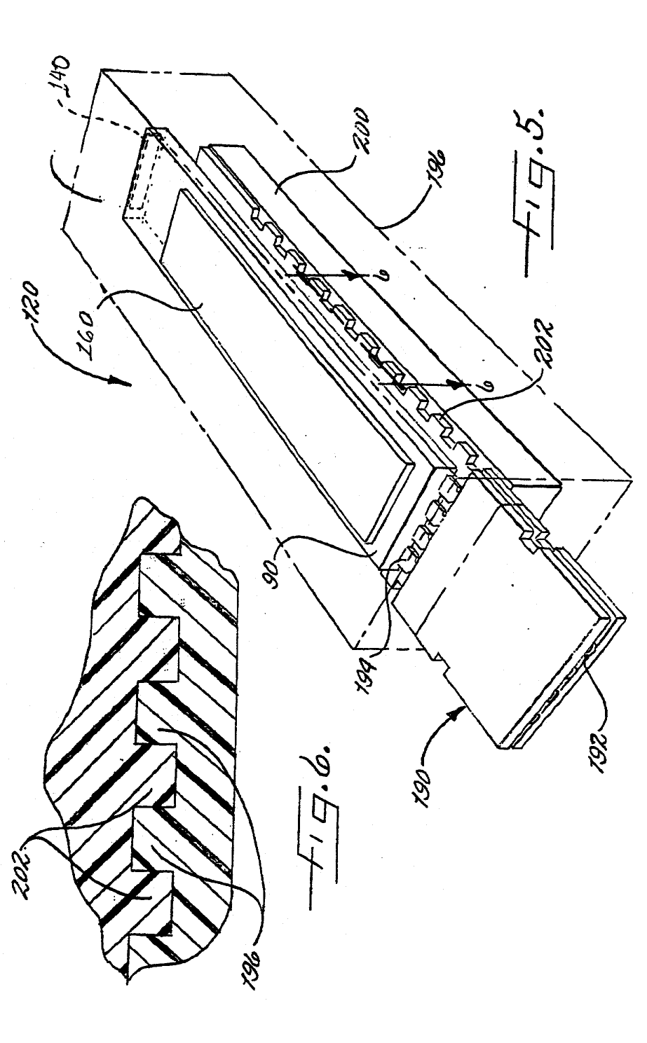

In many circumstances, the optimal trade-off of sensing sensitivity and sensing apparatus 40 compactness will be achieved if the sensor 60 and the signal conditioner 80—and, accordingly, the cut plane 92 and the wafer surface 94—are angled orthogonally to one another, as illustrated in FIGS. 1 and 2. Apparatuses having sensing elements and signal conditioners oriented orthogonally to one another are illustrated in Applicants' own U.S. Pat. No. 6,002,252 titled Compact Sensing Apparatus Having Transducer and Signal Conditioner With A plurality of Mounting Pins and U.S. Pat. No. 6,187,609 B1 titled Compact Sensing Apparatus Having Reduced Cross Section and Methods of Mounting. In FIG. 3, for example, the sensor 60 is positioned for maximum sensitivity perpendicularly to a sensed field 70 generated by object 72. The present invention, however, permits the sensor 60 and the signal conditioner 80 to angled relative to each other at any predetermined angle by orienting the cut plane 92 and the wafer surface 94 at substantially the predetermined angle as described above.

Generally, therefore, the cut plane and the wafer surface are oriented relative each other at a predetermined angle greater than one hundred eighty (180) degrees, the predetermined angle being defined as the angle of rotation between an imaginary initial plane extending substantially parallel to the wafer surface of the monolithic semiconductor substrate and an imaginary terminal plane extending substantially parallel to the cut plane of the semiconductor substrate, as illustrated in FIG. 3.

The sensor 60 can be any type of sensor that generates a sensing signal in response to a physical stimulus, the specific type of sensor depending on the nature of the physical stimulus. These include sensors for sensing electrical or magnetic fields, examples of which include Hall-effect cell, magnetoresistor, capacitive, and inductive sensors as well as electric current sensors. Similarly, electromagnetic sensors would include planar antenna arrays and light transducers, for example. Other sensors sense mechanical forces such as the flow or pressure of a liquid or gas, the mechanical stress or weight of an object, or the acceleration of body in motion, examples of which include a strain gauge, accelerometer, and tilt sensor. An example of an apparatuses having orthogonally oriented Hall elements and magnetoresistors is illustrated in Applicants' U.S. Pat. No. 65,670,886 titled Method and Apparatus for Sensing Proximity or Position on an Object Using Near-Field Effects.

A common feature of each of these various type sensors is that each generally exhibits a preferred orientation relative to the electric or magnetic field or the mechanical force being sensed, the preferred orientation being that which maximizes the sensitivity of the sensor. With respect to each, the ordinary environment in which the sensing apparatus is utilized will also dictate that the sensing apparatus be as small as possible. Therefore, the advantages of the present invention as described above will be equally great whatever the type of sensor 60 utilized in the sensing apparatus 40.

A sensing signal generated by the sensor 60 can be too weak to overcome external noise associated with the particular environment or system in which the sensing apparatus 40 is utilized. The sensing signal can be adversely affected by temperature variations in the environment or otherwise contain a large offset. Therefore, the sensing apparatus 40 further includes the signal conditioner 80 that, preferably, is formed in the wafer surface of the seamless monolithic semiconductor substrate 90 and is electrically connected to the sensor 60 to condition the signal generated by the sensor 60 in response to a predetermined physical stimulus as will be understood by those familiar in the art. The signal conditioner 80 can also boost the signal generated by the sensor 60 in order to convey it to a remote sensing monitor or other electrical device electrically connected to the sensing apparatus, generally being connected electrically directly to the signal conditioner 80 itself.

The sensing apparatus 40 preferably also includes at least one electrical conductor extending between the sensor 60 and the signal conditioner 80 to thereby provide a direct conductive path between the sensor 60 and the signal conditioner 80. Specifically, connecting traces are formed on the cut plane 92 and extend along the plane from the sensor 60 to the edge shared by the cut plane 92 and the wafer surface 94 of the seamless monolithic substrate 90. Similarly, connecting traces are formed on the wafer surface 94 and extend from the signal conditioner 80 and connect at the shared edge to the connecting traces formed on the cut plane 92 to electrically connect the sensor 60 and the signal conditioner 80. The connecting traces on the wafer surface, preferably, are metal traces formed by coating a portion of the wafer surface 94 to form a conductive passivation layer of metal and then etching away portions of the passivation layer so to leave only the desired metal traces that form conductive paths along the wafer surface 94. By contrast, the connecting traces formed on the cut plane preferably comprise defined polycrystalline regions. Each is formed of semiconductor material that has been highly doped to form conductive paths along the cut plane 92. Each such polycrystalline conductive path connects to a corresponding methal trace at the shared edge to form a direct conductive path between the sensor 60 and the signal conditioner 80. Thus, the sensing apparatus includes at least one conductive path along which a sensing signal generated in response to a physical stimulus by the sensor 60 is conveyed for signal conditioning to the signal conditioner 80.

FIG. 4 illustrates a second embodiment of a compact sensing apparatus 120 comprising a sensor 140 and a signal conditioner 160 electrically connected thereto via a conductive path, the sensor 140 and the signal conditioner 160, again, being formed in a seamless monolithic semiconductor substrate 170. As illustrated, the compact sensing apparatus 120 further comprises a second conductive path formed by an electrical connector 192 electrically connected to the signal conditioner 160 and extending therefrom to electrically connect to a preselected electrical device positioned remotely from the sensing apparatus 120. The electrical connector 192 preferably connects directly to at least one bonding pad 194 positioned on the seamless monolithic semiconductor substrate 170 to provide an electrical connection between the signal conditioner 160 and the remotely positioned electrical device. The electrical device, itself, can be, for example, a remote sensing monitor.

Preferably, the compact sensing apparatus 120 further comprises a mounting base 190 on which the seamless monolithic semiconductor substrate is positioned. The base can connect directly to the seamless monolithic semiconductor substrate 170 thereby providing support to the sensor 140 and signal conditioner 160 formed therein. The compact sensing apparatus 120 preferably includes as well a housing or encapsulation 196 encapsulating at least a portion of the signal conditioner 160 for providing a protective cover over the signal conditioner 160. The electrical conductor 192 preferably extends through the encapsulation 196 to thereby provide an electrical connection between the sensing apparatus 120 and preselected electrical device positioned outside the encapsulation 196 and remotely from the sensing apparatus 120.

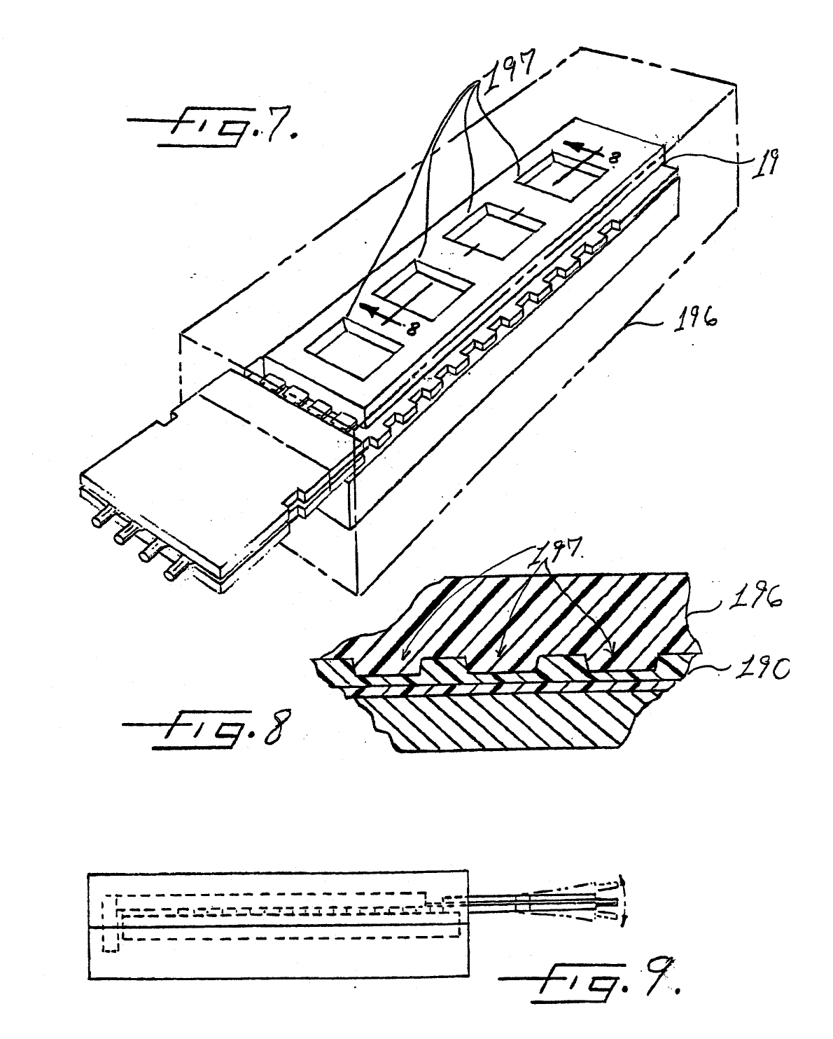

More specifically, as illustrated in FIGS. 4 and 5, the electrical conductor can be a flexible ribbon cable 190 having at least one conductor 192 encased within a ribbon cable cover and electrically connected to the signal conditioner 160 to thereby provide the electrical connection that provides the conductive path between the sensing apparatus 120 and the preselected electrical device positioned outside the encapsulation 196. Alternatively, however, the base can be a lead frame and the electrical conductor a plurality of pins extending from the frame and electrically connected to the signal conditioner 160 to thereby provide the electrical connection that provides the conductive path between the sensing apparatus 120 and the preselected electrical device positioned outside the encapsulation.

As with respect to the first embodiment, the compact sensing apparatus 120 permits the sensor 140 and the signal conditioner 160 to be oriented relative to each other by orienting the wafer surface 174 and the cut plane 172 of the seamless monolithic semiconductor substrate 170 as earlier described. Again, the predetermined angle is greater than one hundred eighty (180) degrees. In many applications, the predetermined angle is at least about two hundred fifty (250) degrees but no greater than about two hundred ninety (290) degrees to thereby reduce the lengthwise extent of the sensing apparatus and to permit the sensor to be angled relative to the physical presence being sensed. In some applications, specifically, the predetermined angle is about two hundred seventy (270) degrees to thereby minimize the lengthwise extent of the sensing apparatus and to permit the sensor to be angled relative to the physical presence being sensed.

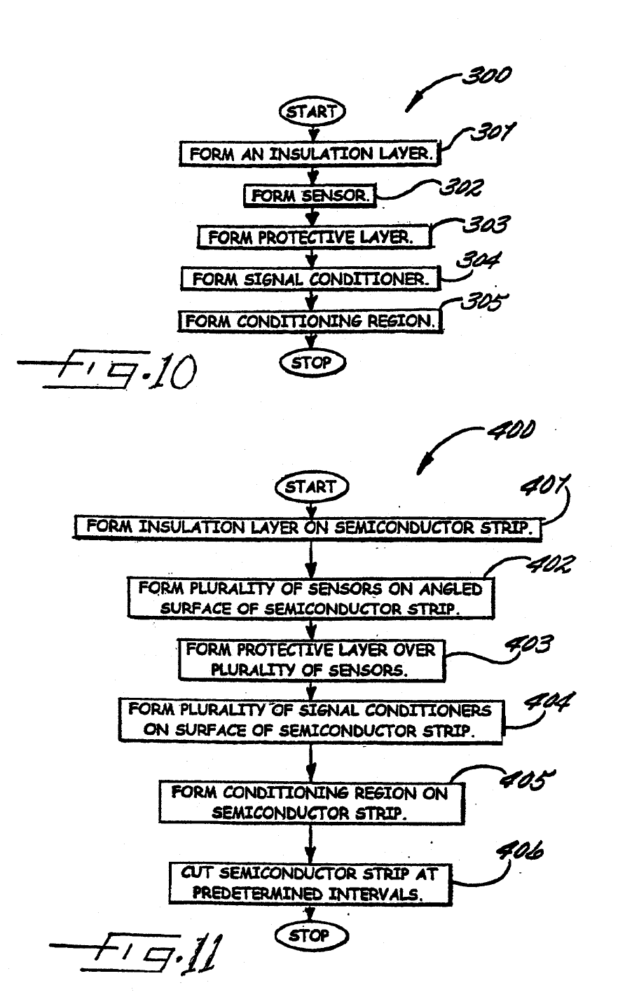

As further illustrated in FIGS. 5 and 6 the mounting base 190 further comprises a roughened surface portion 202 that contacts the encapsulation 196 to thereby increase friction between the base 190 and the encapsulation to thereby reduce the probability that the base 190 will separate from the encapsulation 196. The roughened surface portion 202, for example, can be one or more side portions marked by serrations as illustrated specifically in FIGS. 5 and 6. To further enhance the structural integrity by reducing the probability of separation of the encapsulation 196 from the base 190, the base preferably further comprises at least one encapsulation well 197 as illustrated in FIGS. 6 and 7. An encapsulation well 197, preferably formed in a portion of the base 190 provides a recess within which a portion of the encapsulation 196 extends. The at least one encapsulation well 197 thereby increases the amount of surface contact between the base 190 and the encapsulation 196 and accordingly reduces the probability that the encapsulation 196 will separate from the base 190.

Preferably, the seamless monolithic semiconductor substrate 90, 170 into which the sensor 60, 140 and signal conditioner 80, 160 of the sensing apparatus 40, 120 are formed has been cut from the wafer 100 using the concentrated energy of a laser to cut the wafer 100, the concentrated energy “slicing” the first substrate 90, 170 from the wafer 100 from which the monolithic substrate 90, 170 ultimately is formed as described above. The current industry standard for cutting wafers is to use a diamond saw. This conventional method of wafer cutting, however, generally causes interstitial damage to the substrate on the cut planes of the resulting substrate that is cut from the wafer. The surface anomalies that arise from such cutting can impede the flow of current through the semiconductor substrate. Ordinarily, this poses no problem because conventional methods for forming sensing and other semiconductor-based apparatuses do not form necessary circuitry on the cut planes of the substrate. According to the present invention, however, conductors and bonding pads are formed on a cut plane of semiconductor substrate so as to form a more compact sensing apparatus having an optimally angled sensor and signal conditioner. Preferably, therefore, the wafer 100 is cut by concentrated energy (e.g., coherent electromagnetic radiation generated by a laser) so as to cut the wafer 100 to form a first substrate 90, 170 having a cut plane 92, 172 formed by cuts induced by the concentrated energy used to separate the substrate 90, 170.

The laser, more specifically, delivers energy in the form of coherent electromagnetic radiation. This concentrated energy when imparted by the laser to the crystal lattice of the wafer at least partially serves to create a molecular structure more amenable to electrical conduction by healing cuts and alleviating cracks in the crystalline structure of the substrate 90, 170 and at least partially alleviating from the resulting monolithic semiconductor substrate 90, 170 surface anomalies that would impede the flow of current through polycrystalline conductors formed in the cut plane. To further facilitate formation of a molecular, crystalline structure conducive of electron flow, the monolithic semiconductor substrate 90, 170 preferably also has been annealed prior to forming the sensor 60, 140 and the signal conditioner 80, 160 therein.

Concentrated energy laser cutting, moreover, facilitates another feature of the present invention, namely forming the cut plane 92, 152 on which the sensor 60, 140 is formed at an angle relative to the wafer surface on which the signal conditioner is formed. Because the extent of the sensor 60, 140 and the signal conditioner 80, 160 are substantially parallel to the surfaces 92, 172 and 94, 174, respectively, in which each is formed, angling the cut plane relative to the wafer surface at the predetermined angle ensures that the sensor 60, 140 and the signal conditioner 80, 160 are likewise angled relative to each other substantially at the same predetermined angle.

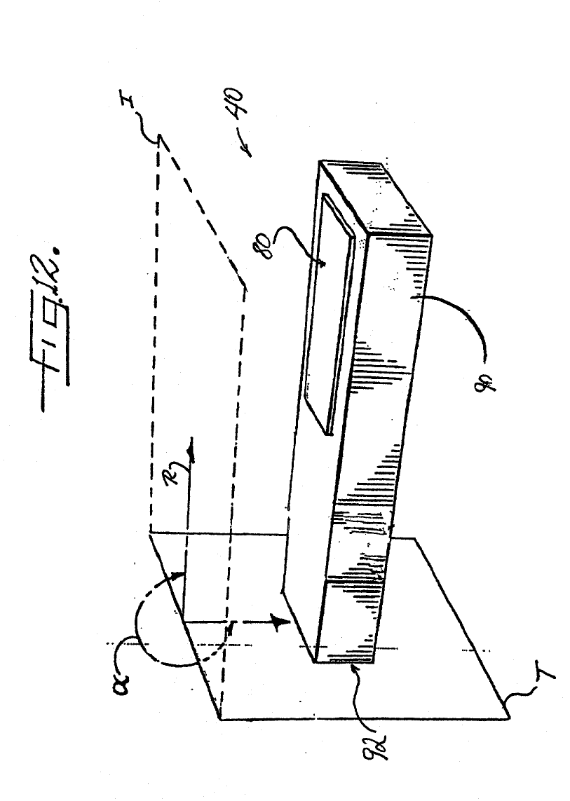

FIG. 10 illustrates method aspects of the present invention relating to the formation of sensing apparatus 40, 120 having a sensor 60, 140 and signal conditioner 80, 160 formed in a seamless monolithic semiconductor substrate 90, 170 and angled relative to each other at a predetermined angle. As described above, the sensor 60, 140 and signal conditioner 80, 160 are formed in a seamless monolithic substrate 90, 170 that has been cut from a semiconductor wafer 100. According to the method 300, the sensor 60, 140 and the signal conditioner 80, 160 are formed in separate discrete steps on distinct planar surfaces—the cut plane 92, 172 and the wafer surface 94, 174 —of a single seamless semiconductor substrate 90, 170. This contrasts sharply with conventional methods in which the sensor and signal conditioning circuitry are formed substantially concurrently and on a common surface, the sensor and signal conditioning circuitry also being connected by metal conductors formed in essentially the same step and on the same surface as the sensor and signal conditioning circuitry.

Conventional methods require such near simultaneity in formation and surface positioning of circuitry because semiconductor devices require that the electrical junctions on and discrete semiconductor regions in the substrate of the device remain sharply defined if the device is to operate efficiently. High temperatures are a normal feature of methods for forming circuitry in a semiconductor substrate. Formation of distinct circuitry portions and their connection with metal conductors in a semiconductor substrate in successive steps at high temperatures poses a problem: separate formations of circuitry requiring dissimilar dopants or different concentrations of dopant would diffuse into one another under the high temperatures ordinarily required during each forming step. So, too, high temperatures would melt any metal conductors already formed in the substrate. One significant advantage of the method aspects of the present invention is that the sensor 60, 140 and signal conditioner 80, 160 are each formed in separate steps on distinct planar surfaces of the same seamless monolithic semiconductor substrate. As explained in detail below, the sensor 60, 140, preferably, is formed over an insulating layer that prevents undesired diffusion of semiconductor material into the seamless monolithic semiconductor substrate 90, 170 during subsequent formation of the signal conditioner 80, 160 on the wafer surface 94, 174 after the sensor 60, 140 has been formed on the cut plane 92, 172.

The method 300 specifically entails forming an insulation layer on a seamless monolithic semiconductor substrate prior to forming the sensor 60, 140 and polycrystalline conductors that will connect the sensor 60, 140 to the signal conditioner 80, 160, both the sensor 60, 140 and conductors being formed in the cut plane 92, 172 (Block 301). The insulating layer is formed behind the cut plane 92, 172 in the seamless monolithic semiconductor substrate 90, 170 and serves as a barrier between the cut plane 92, 172 in which the sensor is formed and the wafer surface 94, 174 in which the signal conditioner 80, 160 is formed. The insulating layer, more specifically, is formed from a material such as silicon oxide (SiO₂) and with sufficient thickness in the seamless monolithic semiconductor substrate 90, 170 as to prevent diffusion of semiconductor material used to form the sensor 60, 140 and conductors of polycrystalline material in the cut plane 92, 172 during subsequent formation of the signal conditioner 80, 160 in the wafer surface 94, 174 of the seamless monolithic semiconductor substrate 90, 170.

After formation of the insulating layer, the sensor 60, 140 and conductors connected to the sensor 60, 140 are formed in the cut plane 92, 172 of the seamless monolithic semiconductor substrate 90, 170 (Block 302). The sensor can be any device responsive to a predetermined physical stimulus, which generates a sensing signal in response to the physical stimulus. The sensor typically will comprise at least one rectangular or square conducting plate and at least one electrical connection attached thereto such that the sensor conducts electrons or holes thus serving as a current carrier as will be well understood by those skilled in the art. For example, the sensor may be a Hall cell having four electrical connections, one per side of a square plate. The sensor, alternatively, can be a capacitive sensor that typically has two plates, one typically be smaller than the other, and each having an signal conductor at an end thereof.

Yet a third example of a sensor is a strain gauge having conductors extending lengthwise thereto and forming electrical connections at each end. Still a fourth example of a sensor is an accelerometer or tilt sensor comprising a rectangular or square plate suspended over a recessed or voided portion in the substrate and having at least one electrical connection connected to each opposing side thereof. A portion of a conductive path between the sensor 60, 140 and the signal conditioner 80, 160 is formed by at least one polycrystalline conductor extending from an electrical connector of the sensor 60, 140. The polycrystalline conductor extends then along the cut plane 92, 172 from the sensor 60, 140 to the edge of seamless monolithic substrate where the cut plane 92, 172 meets the wafer surface 94, 174.

In a subsequent step of the method 300, preferably, a protective layer is formed over the sensor (Block 303). The signal conditioner 80, 160 is then formed during the next step of the method (Block 304). More specifically, the step entails etching away any passivation material that may be left from the prior forming steps and that may extend over the edge where the cut plane 92, 172 meets the wafer surface 94, 174, the material being the result. The signal conditioner 80, 160, preferably is formed with dopants and polycrystalline material in accordance with the precise properties desired for the signal conditioning circuitry as will be readily understood by those skilled in the art. Finally, a conditioning region is formed in which the conductive path between the sensor 60, 140 and the signal conditioner 80, 160 is completed by electrically connecting the polycrystalline conductors formed in the cut plane 92, 172 of the seamless monolithic semiconductor substrate 90, 170 to conductors extending along the wafer surface 94, 174 thereof and connected to the signal conditioner 80, 160.

Preferably, the conductors are metal conductors formed from a metal passivation layer formed on a portion of the wafer surface 94, 174 and then etched to leave metal traces defining metal conductors. The conductive path between the sensor 60, 140 and the signal conditioner, then is completed with at least one metal conductor connected to the signal conditioner 80, 160 and electrically connected at the edge of the substrate to at least one polycrystalline conductor connected to the sensor 60, 140, the edge again being the edge shared by the cut plane 92, 172 and the wafer surface 94, 174 of the seamless monolithic semiconductor substrate 90, 170.

This method aspect of the present invention further can comprise positioning the seamless monolithic semiconductor substrate 170 on a mounting base 190, encasing at least the signal conditioner 160 in an encapsulation 196, and connecting a conductor to a bonding pad 194 that is electrically connected to the signal conditioner to thereby permit the sensing apparatus 120 to be connected to a remote electrical device such as a sensing monitor. For example, the method can entail placing the monolithic semiconductor substrate on a flexible ribbon cable. Alternatively, the monolithic semiconductor substrate can be placed on a lead frame with metal pins. Further, with respect to the substrate mounted on a flexible ribbon cable, for example, the encapsulation 196 can be formed by placing the seamless monolithic semiconductor substrate 170 having a sensor 140 and signal conditioner 180 formed therein in a plastic molding machine that will mold a cylindrically shaped housing around the substrate with the sensor 140 at one end of the cylindrical housing and the ribbon cable extending outwardly from an opposing end thereof. With respect to the seamless monolithic semiconductor substrate 170 having a sensor 140 and signal conditioner 180 formed therein and mounted on a lead frame, the frame and pins connected thereto can be encapsulated in an industry-standard transistor package such as the TO-92 or TO-110 type familiar to those skilled in the art.

FIGS. 11 and 12 illustrates an additional method aspect of the present invention, the method directed to efficiently forming a plurality of sensing apparatuses, each having a sensor 60, 108 and signal conditioner 80, 104 angled relative to each other at a predetermined angle α and formed in a seamless monolithic semiconductor substrate 90, 110. As illustrated by way of example of FIG. 12. a perspective view of a sensing apparatus according to the present invention includes a predetermined angle (α) between an imaginary plane (I) parallel to a substantially planar open surface of a substrate 90 with reference line (12) for defining angle α relative to cut plane 92. A preferred method 400 for forming the plurality of sensing devices according to present invention entails slicing a semiconductor wafer 100 as described above, preferably using laser cutting methods. The wafer is sliced to form one or more primary semiconductor substrates 106 having a lateral extent corresponding to the length of the wafer surface 94, 174 in which the signal conditioner 80, 160 will be formed. (See FIGS. 1 and 2.) Preferably, a plurality of such primary substrates will be formed, each having a lateral extent corresponding to the length of the wafer surface in which a signal conditioner will be formed. Moreover, each substrate preferably will be annealed as earlier described so as to at least partially alleviate cracks that otherwise could propagate through the substrate. The plurality of primary substrates 106 can be turned on end and stacked closely together, the substrates being held, for example, by a metal band attached around the outer edges of the strips with lips folded over the strips.

As illustrated in FIG. 11, the method 400 further entails forming an insulating layer as already described on a portion of each substrate to prevent diffusion of semiconductor and other polycrystalline materials during the formation of signal conditioning circuitry after sensors have been formed on cut planes 109 of the plurality of semiconductor substrates 106 (Block 401). A plurality of sensors 60, 108 are then formed spaced apart in the cut planes 92, 109 of the substrates 106 (Block 402). Polycrystalline conductors corresponding to each of the sensors 60, 108 are also formed in the cut planes 109 of the plurality of semiconductor substrates 106. A protective layer is formed over the sensors 60, 108 (Block 403). Each of the plurality of substrates 106 is again turned, preferably to lie flat on a plate and held in place using, for example, an epoxy. A plurality of signal conditioners 104 is formed in the wafer surfaces 107 of the plurality of semiconductor substrates 106 (Block 404). The plurality of signal conditioners 104 preferably is each formed with dopant and/or polycrystalline materials as will be understood by those skilled in the art. A metal passivation layer is formed on the substrates 106 and then etched to leave metal traces forming metal conductors connected to the signal conditioners 80, 104. A conditioning regions is formed in the semiconductor substrate so as to connect to the polycrystalline conductors formed in the cut planes 109 of the substrates 106 the metal conductors formed on the wafer surfaces 107 of the plurality of semiconductor substrates 106 (Block 405). The polycrystalline conductors and the metal conductors jointly form conductive paths between each of the sensors 60, 108 and corresponding signal conditioners 80, 104 as described above. Finally, each of the substrates 106 is cut between each of the spaced-apart sensors 60, 108 and its corresponding signal conditioner 80, 104 to thereby yield a plurality of seamless monolithic semiconductor substrates 90, 110, each having a sensor 60, 108 and signal conditioner 80, 104 angled relative to each other at a predetermined angle.

In the drawings and specification, there have been disclosed a typical preferred embodiment of the invention, and although specific terms are employed, the terms are used in a descriptive sense only and not for purposes of limitation. The invention has been described in considerable detail with specific reference to these illustrated embodiments. It will be apparent, however, that various modifications and changes can be made within the spirit and scope of the invention as described in the foregoing specification and as defined in the appended claims.

That claimed is:

1. A compact sensing apparatus comprising:
a seamless monolithic semiconductor substrate formed from a semiconductor wafer and having a wafer surface and a cut plane, the wafer surface being oriented relative to the cut plane at a predetermined angle greater than one hundred eighty (180) degrees to thereby enhance the compactness of the sensing apparatus, the predetermined angle being defined as the angle of rotation between an imaginary initial plane extending substantially parallel to the wafer surface of the monolithic semiconductor substrate and an imaginary terminal plane extending substantially parallel to the cut plane of the semiconductor substrate;
a sensor formed in the cut plane of the monolithic semiconductor substrate for generating a sensing signal in response to a predetermined physical stimulus; and
a signal conditioner formed in the wafer surface of the monolithic semiconductor substrate and electrically connected to the sensor for conditioning the sensing signal.

2. A compact sensing apparatus as defined in claim 1, the apparatus further comprising at least one polycrystalline conductor and at least one corresponding metal conductor, the at least one polycrystalline conductor formed in the cut plane of the seamless monolithic semiconductor substrate and electrically connected to the sensor formed therein, the at least one metal conductor formed on the wafer surface of the seamless monolithic semiconductor substrate and electrically connected to the signal conditioner formed therein, and the at least one polycrystalline conductor connecting to the corresponding at least one metal conductor at an edge portion of the seamless monolithic semiconductor substrate to thereby form at least one conductive path between the sensor and the signal conditioner, the edge portion being the edge shared by the wafer surface and the cut plane.

3. A compact sensing apparatus as defined in claim 2, wherein the at least one direct conductive path between the sensor and the signal conditioner defines a first conductive path, and wherein the apparatus further comprises a second conductive path provided by an electrical conductor electrically connected to the signal conditioner and extending therefrom to a preselected electrical device positioned remotely from the sensing apparatus to thereby form a conductive path between the compact sensing apparatus and the preselected electrical device.

4. A compact sensing apparatus as defined in claim 3, further comprising a base on which the monolithic substrate is positioned for providing support thereto and an encapsulation encapsulating at least a portion of the signal conditioner for providing a protective cover therefore, the second conductor extending through the encapsulation to thereby provide an electrical connection between the sensing apparatus and a preselected electrical device positioned outside the encapsulation.

5. A compact sensing apparatus as defined in claim 4, wherein the second conductive path comprises a flexible ribbon cable having at least one conductor encased within the ribbon cable and electrically connected to the signal conditioner to thereby provide an electrical connection between the sensing apparatus and the preselected electrical device positioned outside the encapsulation.

6. A compact sensing apparatus as defined in claim 4, wherein the base is a lead frame and the second conductive path is a plurality of pins extending from the frame and electrically connected to the signal conditioner to thereby provide an electrical connection between the sensing apparatus and the preselected electrical device positioned outside the encapsulation.

7. A compact sensing apparatus as defined in claim 1, wherein the predetermined angle is at least about two hundred fifty (250) degrees but no greater than about two hundred ninety (290) degrees to thereby reduce the lengthwise extent of the sensing apparatus and to permit the sensor to be angled relative to the physical presence being sensed.

8. A compact sensing apparatus as defined in claim 1, wherein the predetermined angle is at least about two hundred seventy (270) degrees to thereby minimize the lengthwise extent of the sensing apparatus and to permit the sensor to be angled relative to the physical presence being sensed.

9. A compact sensing apparatus comprising:
a seamless monolithic semiconductor substrate formed from a semiconductor wafer and having a wafer surface and a cut plane, wafer surface being oriented relative to the cut plane at a predetermined angle of two hundred seventy (270) degrees so that the wafer surface and cut plane are oriented orthogonally with respect to each other to thereby enhance compactness, the predetermined angle being defined as the angle of rotation between an imaginary initial plane extending substantially parallel to the wafer surface of the semiconductor substrate and an imaginary terminal plane extending substantially parallel to the cut plane of the monolithic semiconductor substrate;
a sensor formed in the cut plane of the monolithic semiconductor substrate for generating a sensing signal in response to a predetermined physical stimulus;
a signal conditioner formed on the wafer surface of the monolithic semiconductor substrate and electrically connected to the sensor for conditioning the sensing signal;
a base on which the monolithic semiconductor substrate is mounted for providing base support to the substrate-mounted sensor and signal conditioner;
an encapsulation connected to the base and encapsulating the signal conditioner mounted thereon to provide a protective covering for the signal conditioner; and
an electrical conductor electrically connected to the signal conditioner and extending outside the encapsulation for connecting the sensing apparatus to a preselected device.

10. A compact sensing apparatus as defined in claim 9, wherein the monolithic semiconductor substrate formed from a semiconductor wafer is formed by cutting the semiconductor wafer with concentrated energy in the form of coherent electromagnetic radiation generated by a laser and delivered to the semiconductor wafer to cut therefrom the seamless monolithic semiconductor substrate and at least partially alleviate surface anomalies that would impede the flow of electrical current in polycrystalline conductors formed in the seamless monolithic semiconductor substrate.

11. A compact sensing apparatus as defined in claim 9, wherein the seamless monolithic semiconductor substrate formed from a semiconductor wafer has been cut at an angle to thereby form the cut plane at the predetermined angle relative to the wafer surface.

12. A compact sensing apparatus as defined in claim 9, wherein the seamless monolithic semiconductor substrate has been annealed prior to forming the sensor and the signal conditioner therein.

13. A compact sensing apparatus as defined in claim 9, the apparatus further comprising a passivation layer extending at least partially over the sensor to thereby provide a protective covering over the sensor.

14. A compact sensing apparatus as defined in claim 9, wherein the electrical connection between the sensor and the signal conditioner comprises at least one polycrystalline conductor formed in the cut plane and at least one metal conductor formed on the wafer surface, the at least one polycrystalline conductor being connected to the senor and extending therefrom along the wafer surface to an edge of the seamless monolithic semiconductor substrate, the edge being an edge shared by the wafer surface and the cut plane, and the at least one metal conductor being connected to the signal conditioner and extending therefrom along the wafer surface to the edge of the seamless monolithic semiconductor substrate shared by the wafer surface and the cut plane.

15. A compact sensing apparatus as defined in claim 9, wherein the electrical conductor electrically connected to the signal conditioner and extending outside the encapsulation is a flexible ribbon cable having at least one conductor that is encased within the ribbon cable and that electrically connects to a preselected electrical device positioned outside the encapsulation.

16. A compact sensing apparatus as defined in claim 9, wherein the base is a lead frame and the electrical conductor electrically connected to the signal conditioner and extending outside the encapsulation is a plurality of pins that extend from the frame and that electrically connect to a preselected electrical device positioned outside the encapsulation.

17. A compact sensing apparatus comprising a sensor formed in a first surface portion of a seamless monolithic semiconductor substrate and a signal conditioner formed in a second surface portion formed in a second surface of the same seamless monolithic semiconductor substrate and a second circuit portion formed in a cut plane of the uncut monolithic substrate.

18. A compact sensing apparatus as defined in claim 17, wherein the seamless monolithic semiconductor substrate has been formed from a semiconductor wafer by cutting the semiconductor wafer using concentrated energy in the form of coherent electromagnetic radiation from a laser to thereby at least partially alleviate on the resulting monolithic semiconductor substrate cut plane surface anomalies that would impede the flow of current in the first circuit portion formed thereon.

19. A compact sensing apparatus as defined in claim 17, wherein the seamless monolithic semiconductor substrate is annealed prior to forming the circuitry thereon.

20. A compact sensing apparatus as defined in claim 17, further comprising an insulating layer within a preselected portion of the seamless monolithic semiconductor substrate, the insulating layer having a thickness sufficient to prevent diffusion of dopant materials between regions of the seamless monolithic semiconductor substrate separated by the insulating layer when the first and second circuitry portions are formed sequentially in the seamless monolithic semiconductor substrate.

21. A compact sensing apparatus comprising a sensor formed on a first surface plane of a monolithic substrate and a signal conditioner formed on a second surface plane of the same seamless monolithic substrate, the signal conditioner being electrically connected to the sensor and oriented with respect to the sensor at a predetermined angle greater than one hundred eighty (180) degrees, the angle defined as the angle of rotation between an imaginary initial plane extending substantially parallel to the signal conditioner and an imaginary terminal plane extending substantially parallel to the sensor.

22. A compact sensing apparatus as defined in claim 21, the apparatus further comprising a pair of bonding pads formed on the seamless monolithic substrate and at least one electrical conductor connected to the pair of bonding pads, one of the pair of bonding pads electrically connected to and positioned adjacent the sensor, the other bonding pad electrically connected to and positioned adjacent the signal conditioner, and the at least one electrical conductor traversing an edge portion of the seamless monolithic substrate between the sensor and the signal conditioner to thereby form a direct conductive path between the sensor and the signal conditioner.

23. A compact sensing apparatus as defined in claim 22, wherein the at least one electrical conductor defines a first electrical conductor, and wherein the apparatus further comprises a second conductor electrically connected to the signal conditioner for providing an electrical connection between the apparatus and a preselected electrical device.

24. A compact sensing apparatus as defined in claim 23, further comprising a base on which the seamless monolithic substrate is positioned for providing support thereto and an encapsulation encapsulating at least a portion of the signal conditioner for providing a protective cover therefore, the second conductor extending through the encapsulation to thereby provide an electrical connection between the sensing apparatus and a preselected electrical device positioned outside the encapsulation.

25. A compact sensing apparatus as defined in claim 24, wherein the second conductor is a flexible ribbon cable having at least one conductor encased within the ribbon cable and electrically connected to the signal conditioner to thereby provide the electrical connection between the sensing apparatus and the preselected electrical device positioned outside the encapsulation.

26. A compact sensing apparatus as defined in claim 24, wherein the base is a lead frame and the second conductor is a plurality of pins extending from the frame and electrically connected to the signal conditioner to thereby provide the electrical connection between the sensing apparatus and the preselected electrical device positioned outside the encapsulation.

27. A compact sensing apparatus as defined in claim 21, wherein the predetermined angle is at least about two hundred fifty (250) degrees but no greater than about two hundred ninety (290) degrees to thereby reduce the lengthwise extent of the sensing apparatus and to permit the sensor to be angled relative to the physical presence being sensed.

28. A compact sensing apparatus as defined in claim 21, wherein the predetermined angle is at least about two hundred seventy (270) degrees to thereby minimize the lengthwise extent of the sensing apparatus and to permit the sensor to be angled relative to the physical presence being sensed.

29. A compact sensing apparatus comprising:
a sensor for generating a sensing signal in response to a predetermined physical stimulus, the sensor formed from the cut plane of a monolithic semiconductor substrate; and
a signal conditioner formed from the wafer surface of the same monolithic semiconductor substrate and electrically connected to the sensor for conditioning the sensing signal, the signal conditioner being oriented relative to the sensor at a predetermined angle greater than one hundred eighty (180) degrees to thereby enhance the compactness of the sensing apparatus, the predetermined angle being defined as the angle of rotation between an imaginary initial plane extending substantially parallel to the signal conditioner and an imaginary terminal plane extending substantially parallel to the sensor.

30. A compact sensing apparatus as defined in claim 29, wherein the monolithic semiconductor substrate has been formed from a semiconductor wafer by cutting the semiconductor wafer using concentrated energy in the form of coherent electromagnetic radiation from a laser to thereby at least partially alleviate from the resulting monolithic semiconductor substrate surface anomalies that would impede the flow of current when the sensor is formed on the cut plane surface created by separating the semiconductor substrate from the semiconductor wafer.

31. A compact sensing apparatus as defined in claim 30, wherein the monolithic semiconductor substrate formed from a semiconductor wafer has been cut at angle to thereby form the cut plane at the predetermined angle relative to the wafer surface.

32. A compact sensing apparatus as defined in claim 31, the apparatus further comprising a base on which the sensor and the signal conditioner are mounted for providing support to the sensor and the signal conditioner.

33. A compact sensing apparatus as defined in claim 32, further comprising an encapsulation encapsulating at least a portion of the sensor and signal conditioner.

34. A compact sensing apparatus as defined in claim 33, wherein at least a portion of the encapsulation contacts a portion of the base and the base further comprises at least one recess formed in a surface portion of the base, recess defining an encapsulation well within which a portion of the encapsulation extends to thereby increase contact between the base and the encapsulation and reduce the probability that the base will separate from the encapsulation when the base and encapsulation are subjected to unequal forces.

35. A compact sensing apparatus as defined in claim 33, wherein at least a portion of a surface of the mounting base is roughened to thereby increase friction at a point of contact between the mounting base and the encapsulation housing to thereby reduce the probability that the base will separate from the encapsulation when the base and encapsulation are subjected to unequal forces.

36. A compact sensing apparatus as defined in claim 29, further comprising an electrical conductor electrically connected to the signal conditioner for providing an electrical connection between the apparatus and a preselected electrical device.

37. A compact sensing apparatus as defined in claim 36, wherein the conductor is a flexible ribbon cable having at least one conductive component encased within the ribbon cable and electrically connected to the signal conditioner to thereby provide the electrical connection between the sensing apparatus and a preselected electrical positioned outside the encapsulation.

38. A compact sensing apparatus as defined in claim 36, wherein the base is a lead frame and the second conductor is a plurality of pins extending from the frame and electrically connected to the signal conditioner to thereby provide the electrical connection between the sensing apparatus and a preselected electrical positioned outside the encapsulation.

39. A compact sensing apparatus as defined in claim 29, wherein the predetermined angle is at least about two hundred fifty (250) degrees but no greater than about two hundred ninety (290) degrees to thereby reduce the lengthwise extent of the sensing apparatus and to permit the sensor to be angled relative to the physical presence being sensed.

40. A compact sensing apparatus as defined in claim 39, wherein the predetermined angle is at least about two hundred seventy (270) degrees to thereby minimize the lengthwise extent of the sensing apparatus and to permit the sensor to be angled relative to the physical presence being sensed.
